(19) United States
(12) Patent Application Publication
(10) Pub. No.: US 2012/0255613 A1
(43) Pub. Date: Oct. 11, 2012

(54) PHOTOVOLTAIC CELL AND METHODS FOR PRODUCING A PHOTOVOLTAIC CELL

(75) Inventors: Milan Vanecek, Praha 4 Modrany (CZ); Ales Poruba, Prague (CZ); Zdenek Remes, Prague (CZ); Jakub Holovsky, Prague (CZ); Adam Purkrt, Prague (CZ); Oleg Babchenko, Prague (CZ); Karel Hruska, Prague (CZ); Neda Neykova, Prague (CZ); Ulrich Kroll, Corcelles (CH); Johannes Meier, Corcelles (CH)

(73) Assignees: FYZIKALNI USTAV AV CR, V.V.I., Praha 8 (CZ); OERLIKON SOLAR AG, TRUEBBACH, Truebbach (CH)

(21) Appl. No.: 13/496,615

(22) PCT Filed: Sep. 16, 2010
(86) PCT No.: PCT/IB10/54179

§ 371 Date: Jun. 27, 2012

Related U.S. Application Data
(60) Provisional application No. 61/243,678, filed on Sep. 18, 2009.
(60) Provisional application No. 61/379,906, filed on Sep. 3, 2010.

(51) Int. Cl. H01L 31/0352; H01L 31/18

(52) U.S. Cl. 136/261; 438/57; 257/E31.126

(57) ABSTRACT

A photovoltaic cell (10) is fabricated by depositing a first transparent conductive layer (12) onto a substrate carrier (11). Portions of the first transparent conductive layer (12) are selectively removed to form a plurality of discrete transparent conductive protruding regions (13) or a plurality of discrete indentations (27) in the first transparent conductive layer (12). A silicon layer (14) comprising a charge separating junction is deposited onto the plurality of discrete protruding regions (13) or onto the plurality of discrete indentations (27) by chemical vapour deposition. A second transparent conductive layer (15) is deposited on the silicon layer (14) by chemical vapour deposition.

The present invention relates to a photovoltaic cell, in particular a thin film silicon solar cell and to methods for producing a photovoltaic cell.

Presently, amorphous silicon solar cells are industrially produced in large quantities by various producers. However, there is a limit for their absolute efficiency when converting solar energy into electricity. Solar cells nowadays are typically deposited as a thin amorphous film (around 300 nm of thickness) on a respective substrate. However, the efficiency of such solar cells is typically below 6%.

The current generated by the solar cell can be increased by increasing the cell thickness, thus allowing more light to be absorbed. Due to the so called Staebler-Wronski effect (SWE), however, this approach does not yield higher efficiency in a long term timescale due to light-created defects in the amorphous Si absorber layer. The SWE can be reduced by introduction of nanocrystallites into the amorphous part, as described e.g. in U.S. patent application Ser. No. 11/744,918 by S. Guha et al. However, defect formation is not completely avoided.

Hence, a present strategy is to increase the light path in a thinner absorber (thickness typically in the 200-300 nm range) by light scattering at nano-rough interfaces and subsequently light trapping in the absorber layer. This process has also some inherent limitations in typical p-i-n cell structures as described and modelled in the scientific literature.

Experimental data show that reducing the amorphous absorber thickness below 200 nm results in increased stability against light soaking, as described in S. Benagli et al., Proceedings of 21st European Photovoltaic Solar Energy Conference, p. 1719, (Dresden 2006). Nevertheless not sufficient light is being absorbed in such thin cells, as it can be modeled by the optical model described in J. Appl. Phys. 96 (2004) 5329 by J. Springer, A. Poruba and M. Vanecek.

Therefore, at present, there is a strong focus on tandem or triple junction solar cells with a thin amorphous layer as the absorber of a p-i-n or n-i-p top cell. The efficiency can be increased this way but the thin amorphous layer, necessary for a good collection of photogenerated carriers remains a limiting factor. Another drawback is a relatively thick bottom layer (for example microcrystalline silicon), which again increased the demand for a high electronic quality of the microcrystalline absorber in order to collect all photogenerated carriers.

It is, therefore, desirable to provide a photovoltaic cell which has an increased, stable efficiency and has a high electronic quality.

A photovoltaic cell is provided which comprises a substrate carrier, a first transparent conductive layer positioned on the substrate carrier and comprising a plurality of discrete transparent conductive protruding regions, the plurality of discrete transparent conductive protruding portions having a diameter in the range of 150 nm to 200 nm and a height of 500 nm to 700 nm, or a plurality of discrete indentations having a diameter in the range of 150 nm to 200 nm and a height of 500 nm to 700 nm. A silicon layer comprising a charge separating junction covers the plurality of discrete transparent conductive protruding regions or the plurality of discrete indentations. A second transparent conductive layer is positioned on the silicon layer.

The plurality of discrete protruding portions comprise material of the first transparent conductive layer. Therefore, in both embodiments, the first transparent conductive layer has a three-dimensional surface comprising generally horizontal portions abutting generally vertical portions. The silicon layer which provides the active component of the photovoltaic cell for converting impinging photons into electricity also has this three-dimensional structure.

Light impinges the substrate in a perpendicular direction to the major surface of the substrate. Due to the protruding regions or indentations of the first transparent conductive layer, the silicon layer and the charge separating junction has a folded structure which follows the contour of the protruding regions or indentations of the first transparent layer.

This results in the photovoltaic cell being optically thicker than a planar arrangement of the layers. However, transport of the photogenerated charge between the electrodes the cell is electrically thin as the thickness of the cell overall is not increased. An increased proportion of the photogenerated charge carriers can be collected in p-i-n type structure even in the less advantageous case of the light-soaked amorphous silicon or a higher defect density nano- and microcrystalline silicon.

The first and second transparent conductive layers may comprise ZnO or a doped ZnO such as boron-doped ZnO or aluminium-doped ZnO. The first and second transparent conductive layers may comprise the same or differing compositions.

The substrate carrier may be a superstrate. The term superstrate refers to a solar cell configuration where the glass substrate is not only used as supporting structure but also as window for the illumination and as part of the encapsulation. During operation the glass is “above” the actual solar cell formed by the two transparent conductive layers and the silicon layer with the charge separating junction or junctions.

The term discrete is used herein to denote that the protruding regions or indentations are spaced at a distance from their immediate neighbour.

In a embodiment, the silicon layer is positioned conformally on the plurality of discrete transparent conductive protruding regions or on the plurality of discrete indentations.

Conformal is defined herein to describe a layer which has a contour which generally matches or corresponds to the contour of the underlying surface on which the layer is positioned.

The silicon layer may comprises a plurality of protrusions having a diameter of 300 nm or greater. These protrusions of the silicon may be formed by a silicon layer coating the discrete protruding portions comprising material of the first transparent conductive layer or by regions of a silicon layer positioned on the first transparent conductive layer positioned between discrete indentations formed in the first transparent conductive layer.

In an embodiment, the charge separating junction has a contour which is conformal to the contour of the first transparent conductive layer. Therefore, the contour of the junction can be controlled by controlling the form of the surface of the first transparent conductive layer.

In an embodiment, the charge separating junction comprises alternately arranged generally vertical and generally horizontal regions. The protruding regions or indentations may, for example, be generally cylindrical to provide a charge separating junction having this contour.

In further embodiments, the second transparent conductive layer is positioned conformally on the silicon layer.

The conformity of the silicon layer and the second transparent conductive layer may be achieved by selecting an appropriate deposition method and/or the conditions used to deposit the layers. For example, the silicon layer may be deposited using plasma enhanced chemical vapour deposition (PECVD). The second transparent conductive layer may be deposited using low pressure chemical vapour deposition (LPCVD).

In an embodiment, the plurality of discrete transparent conductive protruding regions or the plurality of discrete indentations extend generally perpendicular to a major plane of the substrate carrier and in particular generally parallel to the direction of the impinging light. This further increases the efficiency of the photovoltaic cell.

In an embodiment, the plurality of discrete transparent conductive protruding regions or the plurality of discrete indentations are arranged in an approximately ordered array. Such an arrangement can increase the density of the folded charge separating junction. The ordered array may be a hexagonal closed packed arrangement, for example.

The plurality of discrete transparent conductive protruding regions or the plurality of discrete indentations may each have a generally elongate form and may have the form of one of more of a pillar, a cone with or without a tip or a pyramid with or without the tip or a hemisphere. The discrete protruding regions can also be described as nanocolumns or pillars.

In an embodiment, the spacing of the discrete protruding regions of the transparent conductive layer or discrete indentations in the first transparent conductive layer and the thickness of the overlying layers is such that the second transparent conductive layer fills regions between the protruding regions of the silicon layer.

The charge separating junction of the silicon layer may be one of a p-n junction and a p-i-n junction.

In an embodiment, the silicon layer comprises a p-type semiconductor layer, an intrinsic layer and a n-type semiconductor layer of amorphous, nanocrystalline, microcrystalline or recrystallized polycrystalline silicon.

The photovoltaic cell may also be a multi-junction device as well as a single junction device. In an embodiment, the silicon layer comprises a first deposited p-i-n stack with an absorber bandgap larger than the absorber bandgap of a secondly deposited p-i-n stack. The use of different bandgaps enables a higher conversion efficiency of the impinging light to electricity.

The first p-i-n stack may comprise amorphous silicon and the second p-i-n stack comprises nanocrystalline or microcrystalline silicon.

In a further embodiment, the photovoltaic cell includes three p-i-n-junctions. The silicon layer comprises a first p-i-n stack with a first absorber bandgap, a second p-i-n stack having a second absorber bandgap and a third p-i-n stack having a third absorber bandgap, wherein the second absorber bandgap is larger than the third absorber bandgap and the first absorber bandgap is larger than the second absorber bandgap.

For transparent substrates such as glass, the p-type semiconductor layer is positioned on the first transparent conductive layer, the intrinsic layer is positioned on the p-type semiconductor layer and the n-type semiconductor layer is positioned on the intrinsic layer.

If the photovoltaic cell includes a transparent substrate, it may further comprise a reflective layer positioned on the second transparent conductive layer. The reflective layer may comprises a white pigmented dielectric reflective media.

Methods of fabricating a photovoltaic cell are also provided. In a method, a substrate carrier is provided and a first transparent conductive layer is deposited onto the substrate carrier. Portions of the first transparent conductive layer are selectively removed and a plurality of discrete transparent conductive protruding regions are formed. Alternatively, portions of the first transparent conductive layer are selectively removed and a plurality of discrete indentations in the first transparent conductive layer are formed. A silicon layer comprising a charge separating junction is deposited onto the plurality of discrete protruding regions or onto the plurality of discrete indentations by chemical vapour deposition and a second transparent conductive layer is deposited onto the silicon layer by chemical vapour deposition.

Chemical vapour deposition (CVD) is used herein to denote all types of chemical vapour deposition such as plasma enhanced chemical vapour deposition (PECVD), low-pressure chemical vapour deposition (LPCVD) and atmospheric chemical vapour deposition (ACVD).

Chemical vapour deposition processes are used to deposit a material from a volatile precursor onto a substrate. Atmospheric CVD processes are carried out at atmospheric pressure. Low-pressure CVD processes are carried out a sub-atmospheric pressures. This subatmospheric pressure may also be a very low pressure such as less than 10⁻⁶ Pa. These very low pressure CVD processes are called Ultrahigh vacuum CVD (UHVCVD).

Plasma enhanced CVD processes are also carried out at subatmospheric pressure, but additionally a plasma is used to enhance the reaction rate.

The first transparent conductive layer has an undulating surface profile. This undulating surface profile can be transferred to the overlying silicon layer and the charge separation junction by conformal deposition of the silicon layer by chemical vapour deposition to provide a photovoltaic ell with an undulating or folded junction.

A closed layer of a transparent conductive material may be deposited which has a generally uniform thickness to provide the first transparent conductive layer. Regions of the first transparent conductive layer are then selectively removed to produce the plurality of discrete transparent conductive protrusions or the plurality of discrete indentations. The form and dimensions of the protruding regions or indentations may be more closely defined using a removal method. The lateral position of the discrete protruding regions or discrete indentations may also be more closely defined using a removal method, i.e. a top down approach, rather than an additive method, i.e. a bottom up approach.

In an embodiment, the silicon layer is deposited by plasma enhanced chemical vapour deposition. The first transparent conductive layer and/or the second transparent conductive layer may be deposited by low pressure chemical vapour deposition.

These methods can produce respective layers which conform to the underlying structure and which have a high quality in terms of their function and coverage. The silicon layer is deposited conformally onto the plurality of discrete transparent conductive protruding regions or onto the plurality of discrete indentations and the second transparent conductive layer is deposited conformally onto the silicon layer.

The contour of the silicon layer and of the charge separating junction is largely determined by the contour of the outer surface of the first transparent layer so that the length of the junction can be increased by increasing the surface area of the first transparent conductive layer by providing the plurality of discrete protruding regions or the plurality of discrete indentations.

The portions of the first transparent conductive layer may be removed in a number of different ways.

In an embodiment, the portions of the first transparent conducive layer are selectively removed to form a closed sub-layer from which the plurality of discrete transparent conductive protruding regions extend. The plurality of discrete transparent conductive protruding regions comprise material of the first transparent conductive layer. This arrangement can be achieved by stopping the selective removal process before all of the first layer is removed and the substrate exposed.

In an embodiment, a plurality of discrete metal islands are deposited on the first transparent conductive layer and regions of the first transparent conductive layer positioned outside of the metal islands are removed by selective etching to produce a plurality of discrete protruding regions comprising material of the first transparent conductive layer. The discrete metal islands act as a resist and are not affected by the etching process.

In a further embodiment, a patterned resist layer is produced on the closed layer and discrete indentations etched in the first transparent conductive layer. The patterned resist layer has a plurality of discrete openings exposing discrete regions of the underlying first transparent conductive layer. These discrete exposed areas are removed by etching.

If an etching method is used to remove regions of the first transparent conductive layer, the depth of the indentations or the height of the protruding regions is controlled by the etching time.

The first transparent conductive layer may structured by reactive ion etching, wet chemical etching or photolithography to produce the plurality of discrete protruding regions of a transparent conductive material or the plurality of discrete indentations.

In a further embodiment, the first transparent conductive layer is structured by electron beam lithography to produce the plurality of discrete protruding regions of a transparent conductive material or lithography is used to produce the plurality of discrete indentations.

The plurality of protruding regions or the plurality of indentations may be structured so that they each have the form of one or more of a pillar, a pyramid, a hemisphere or a cone.

The portions of the first transparent layer may be removed to produce the plurality of discrete transparent conductive protruding portions with a diameter in the range of 150 nm to 200 nm and a height of 500 nm to 700 nm. Alternatively, the portions of the first transparent layer are removed to produce the plurality of discrete indentations with a diameter in the range of 150 nm to 200 nm and a height of 500 nm to 700 nm.

After deposition of the silicon layer onto these protruding regions of indentations, an outer surface of the silicon layer comprises a plurality of protruding regions having a diameter of at least 300 nm.

These dimension can result in the solar cell having an efficiency of 10% or greater for amorphous silicon or 15% or greater for Mircromorph silicon.

The second transparent conductive layer may also be deposited conformally onto the silicon layer or non-conformally to fill regions between adjacent protruding regions or to fill the indentations lined with silicon.

In an embodiment, three sub-layers are deposited to form the silicon layer and a p-i-n or n-i-p charge separating junction. The doping type, i.e. positively charged, p-type, or negatively charged, n-type, or intrinsically doped, i-type, is adjusted during deposition so as to provide the desired order of the three sub-layers.

In embodiments in which the substrate carrier is transparent at optical wavelengths, for example in embodiments in which the substrate carrier is glass, a further reflective layer may be deposited onto the second transparent conductive layer.

Embodiments are now described with reference to the accompanying drawings.

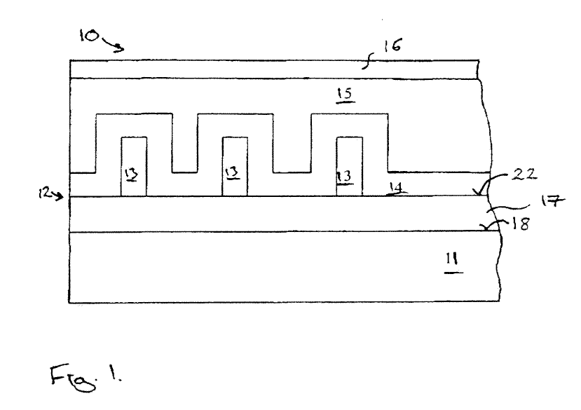

FIG. 1 illustrates a schematic cross-sectional view of a photovoltaic cell according to a first embodiment,

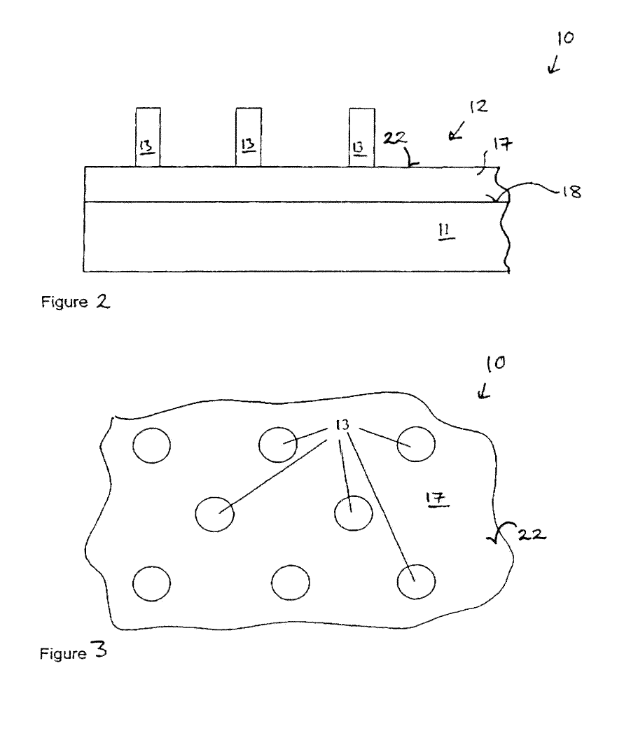

FIG. 2 illustrates a schematic top view of a substrate with a plurality of transparent conductive pillars,

FIG. 3 illustrates a top view of the substrate of FIG. 2,

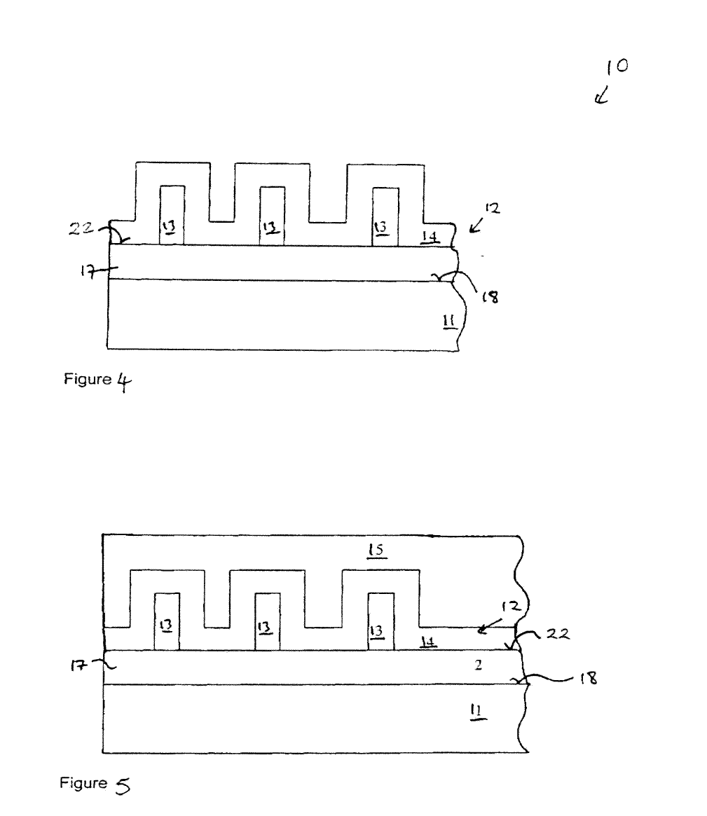

FIG. 4 illustrates the deposition of a thin film silicon photovoltaic structure onto the substrate of FIG. 2,

FIG. 5 illustrates the deposition of a second transparent conductive layer onto the substrate of FIG. 4,

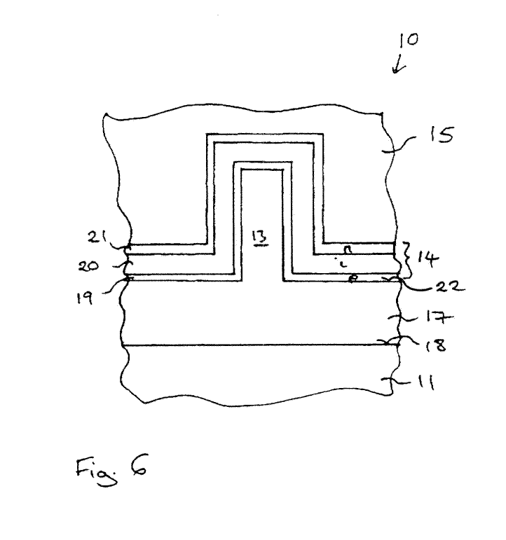

FIG. 6 illustrates the p-i-n structure of the silicon layer of FIGS. 2 to 5,

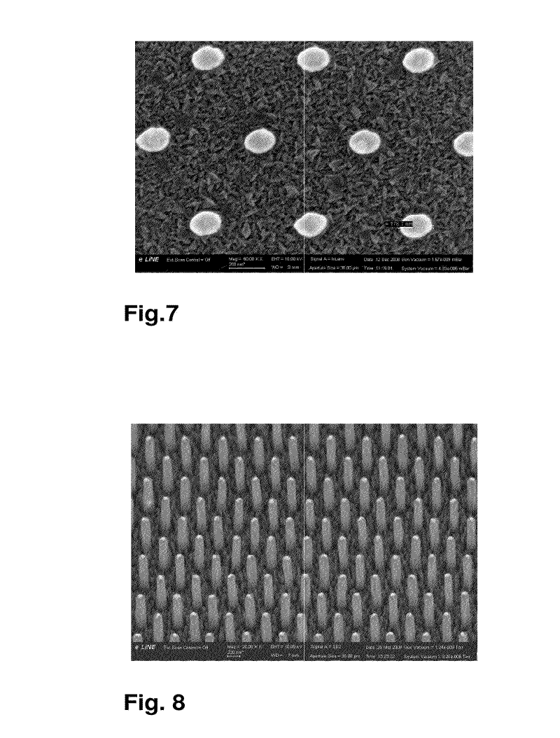

FIG. 7 illustrates a SEM (scanning electron microscope) micrograph of a ZnO layer with deposited metallic masking dots,

FIG. 8 illustrates a SEM micrograph of a tilted top view of ZnO nanocolumn array produced by Reactive Ion Etching,

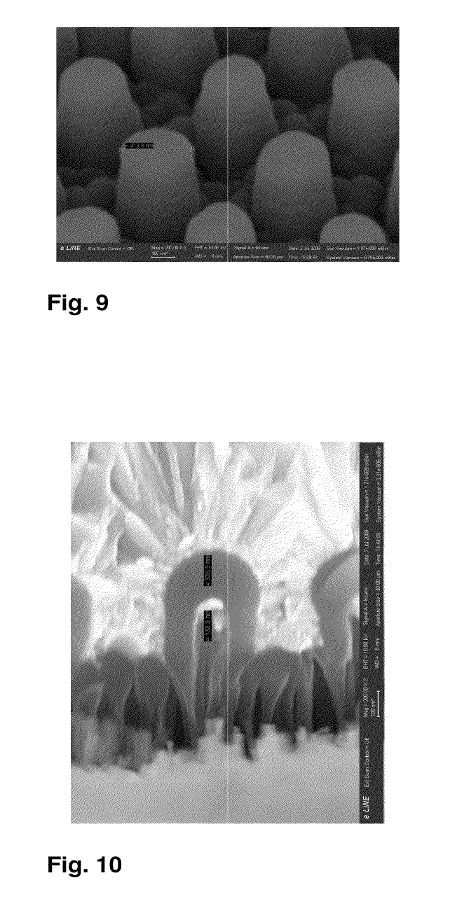

FIG. 9 illustrates a SEM micrograph of a tilted top view of an array of ZnO nanocolumns covered by an intrinsic amorphous Si layer,

FIG. 10 illustrates a SEM micrograph of a detail of the cross section of a photovoltaic cell,

FIG. 11 illustrates FTPS spectra of a folded amorphous silicon absorber layer,

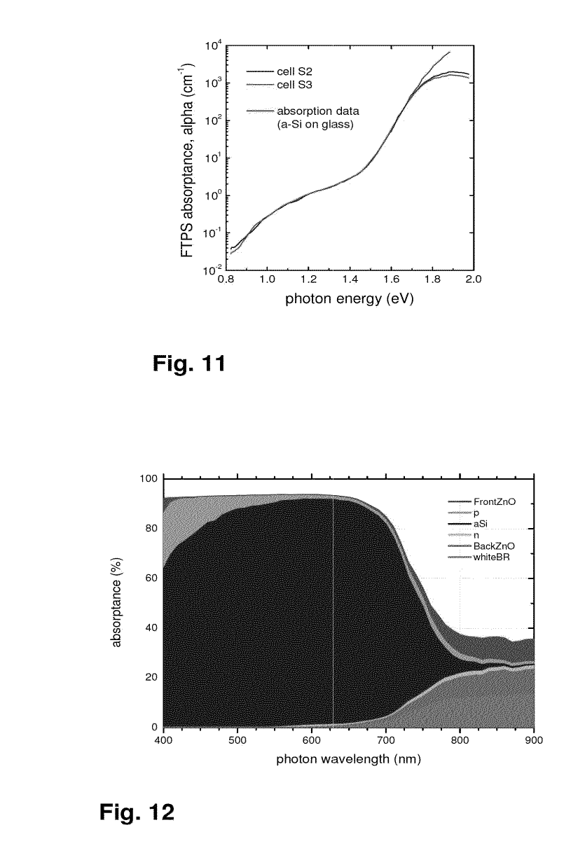

FIG. 12 illustrates optical absorption modeling in a 3-D nanostructured a-Si (amorphous silicon) solar cell with ZnO nanocolumns,

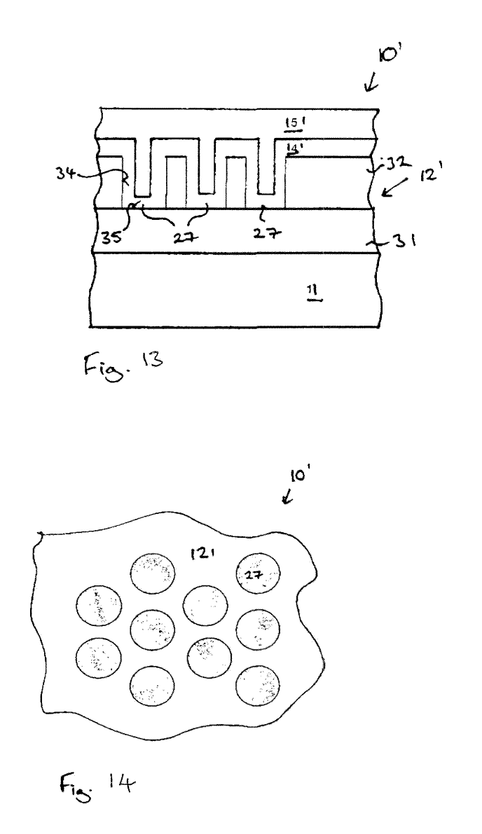

FIG. 13 illustrates a photovoltaic cell according to a further embodiment which includes a first transparent conductive layer including a plurality of discrete indentations,

FIG. 14 illustrates a top view of a first transparent conductive layer including a plurality of discrete indentations,

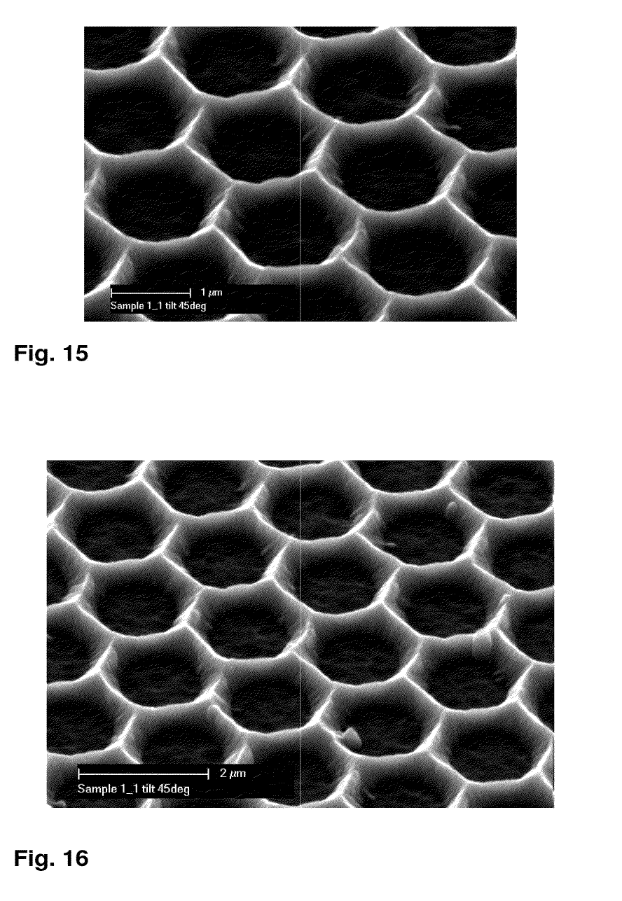

FIG. 15 illustrates a SEM micrograph of a first transparent conductive layer including a plurality of discrete indentations,

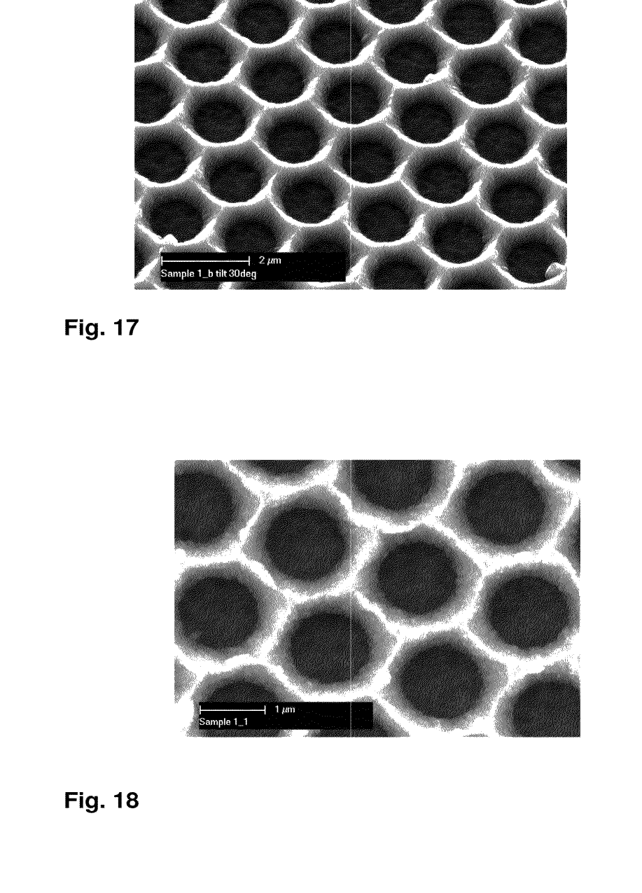

FIG. 16 illustrates a SEM micrograph of a first transparent conductive layer including a plurality of discrete indentations,

FIG. 17 illustrates a SEM micrograph of a first transparent conductive layer including a plurality of discrete indentations,

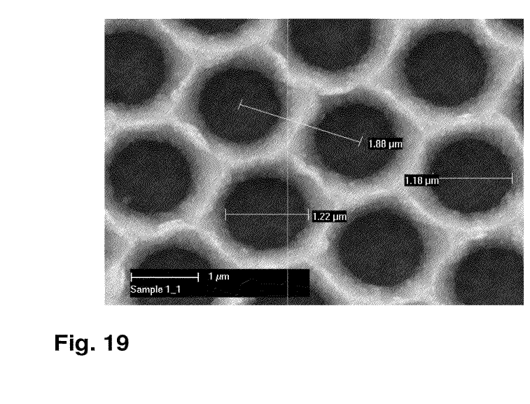

FIG. 18 illustrates a SEM micrograph of a first transparent conductive layer including a plurality of discrete indentations,

FIG. 19 illustrates a SEM micrograph of a first transparent conductive layer including a plurality of discrete indentations,

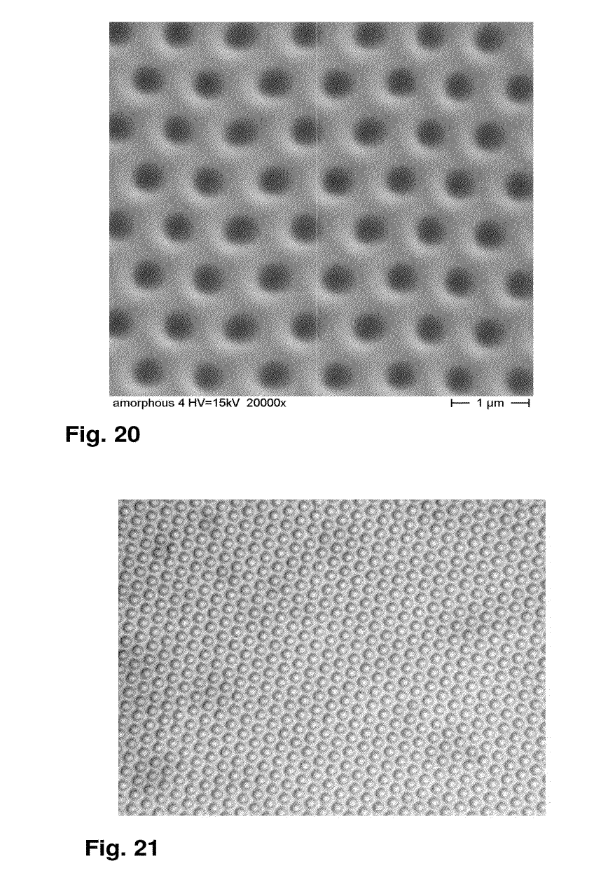

FIG. 20 illustrates a SEM micrograph of a mask used to fabricate a first transparent conductive layer with a plurality of discrete indentations,

FIG. 21 illustrates an optical micrograph of a mask used to fabricate a first transparent conductive layer with a plurality of discrete indentations,

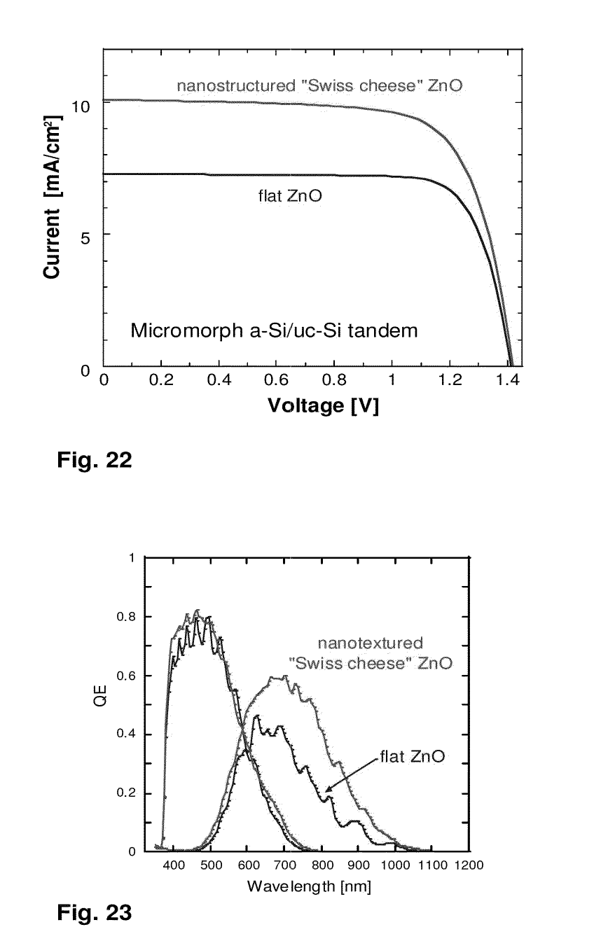

FIG. 22 illustrates a graph showing a comparison of the current/voltage characteristics of a tandem solar cell deposited onto a first transparent conductive layer including a plurality of discrete indentations and a flat transparent conductive layer,

FIG. 23 illustrates a graph showing a comparison of the quantum efficiency of a tandem solar cell deposited onto a first transparent conductive layer including a plurality of discrete indentations and a flat transparent conductive layer.

FIG. 1 illustrates a schematic cross-sectional view of a photovoltaic cell 10 according to a first embodiment. The photovoltaic cell 10 includes a substrate in the form of a glass superstrate 11, a first transparent conductive layer 12 positioned on the superstrate 11, a silicon layer 14 deposited on the first transparent conductive layer 12, a second transparent conductive layer 15 positioned on the silicon layer 14 and a reflective layer 16 positioned on the second transparent conductive layout 15.

The glass superstrate 11 is considered the front of this photovoltaic cell as the photons, in this embodiment solar energy, impinge the glass superstrate 11. The reflective layer 16 is considered the back. The first transparent conductive layer 12 can be termed the front transparent conductive layer and the second transparent conductive layer 15 as the back transparent conductive layer.

The first transparent conductive layer 12 includes a continuous sub-layer 17 positioned on the superstrate 11 and an ordered array of discrete protruding regions in the form of pillars 13 of a transparent conductive material. The pillars 13 extend generally perpendicularly to the major surface 18 of the glass superstrate 11 and to the sub-layer 17.

As can be seen in the top view of FIG. 2, the pillars 13 are arranged in an approximately hexagonal closed packed array and each has a generally cylindrical form.

The transparent conductive pillars 13 have a diameter of around 150 nanometres and a height of around 500 nanometres. The transparent conductive material is zinc oxide doped with either aluminium or boron in this embodiment. However, other transparent conductive oxides such as indium tin oxide may also be used.

The silicon layer 14 is positioned conformally over the surface of the sub-layer 17 and pillars 13 of the first transparent conductive layer 12. The silicon layer 14 has a charge separating junction, in this embodiment a p-i-n junction which is illustrated in the detailed view of FIG. 6. The silicon layer may also be described as the absorber layer or the active photovoltaic layer.

In the first embodiment, the second transparent conductive layer 15 fills the spaces between the columnar structures formed by the first transparent oxide layer and silicon layer 14 and extends continuously across the substrate 11 so that its upper surface is generally parallel to the major surface 18 of the substrate 11.

Light impinges the substrate 11 in a perpendicular direction to the major surface of the substrate. Due to the nanoscale pillars 13 of the first transparent conductive layer 12 and the conformal contour of the silicon layer 14, the p-i-n junction as well as the silicon absorber layer has a folded structure. This results in the photovoltaic cell 10 being optically thicker than a planar arrangement of the layers. However, transport of the photogenerated charge between the electrodes the cell is electrically thin as the thickness of the cell overall is not increased. An increased proportion of the photogenerated charge carriers can be collected in p-i-n type structure even in the less advantageous case of the light-soaked amorphous silicon or a higher defect density nano- and microcrystalline silicon.

FIGS. 2 to 6 illustrate the fabrication of the photovoltaic cell of FIG. 1 according to an embodiment.

FIG. 2 illustrates a schematic cross-sectional view of the substrate 11 after the fabrication of the first transparent conductive layer 12 comprising a continuous transparent conductive oxide (TCO) sub-layer 17 positioned on major surface 18 of the substrate 11 and TCO nano-column array 13 extend from outer surface 22 of the sub-layer 17.

FIG. 3 illustrates a top view of the substrate with a transparent conductive oxide (TCO) sub-layer 17 and TCO array of nanoscale TCO pillars 13. The pillars 13 have a generally cylindrical form and are arranged in an approximately hexagonal closed packed array.

FIG. 4 illustrates a schematic cross-sectional view of the superstrate 11, the TCO sub-layer 17 and TCO nano-column array 13 and further silicon layer 14 deposited conformally on the TCO sub-layer 17 and TCO nano-column array 13. The silicon layer has a p-i-n structure of amorphous silicon illustrated in FIG. 6.

A similar structure with increased height of nanopillars 13 and slightly increased spacing between the nanopillars 13 can be used for tandem or triple junction cells.

FIG. 5 illustrates the structure of FIG. 4 after the deposition of the second transparent conductive layer 15, for example, of a transparent conductive oxide, in particular of ZnO doped with aluminium. The silicon layer 14 is covered with the second transparent conductive layer 15 which acts as a collecting electrode.

FIG. 6 illustrates the p-i-n structure of the silicon layer 14 which provides the active photovoltaic layer or absorber layer of the photovoltaic cell 10. The silicon layer 14 includes three sub-layers. A first sub-layer 19 is deposited conformally on the sub-layer 17 and pillars 13 of the first transparent conductive layer 12. The first sub-layer 19 is positively doped and provides the p-layer of the p-i-n junction. The second sub-layer 20 is intrinsic silicon and is positioned conformally on the first sub-layer 19 to provide the i-layer. The third sub-layer 21 is negatively-doped silicon and is positioned conformally on the intermediate second sub-layer 20 to provide the n-layer of the charge separating junction. The silicon layer may have the structure and be fabricated by a method disclosed in U.S. Pat. No. 6,309,906 which is incorporated herein by reference in its entirety.

The plurality of pillars may be fabricated by selectively removing the uppermost portion of the first transparent conductive layer.

In an embodiment, a precursor film of a transparent conductive material such as ZnO or aluminium-doped ZnO is deposited on a substrate. A mask layer is deposited on the precursor layer and structured to provide a plurality of discrete islands corresponding to the desired arrangement of pillars. The mask layer comprises a material which is largely or entirely resistant to an etch used to remove the material of the precursor film.

The substrate with the precursor layer and structured mask is then subjected to an etching treatment to remove material of the precursor film in regions not covered by the structured mask. The etching is carried out until a plurality of discrete pillars of zinc oxide protrude form a continuous sub-layer of zinc oxide and, in particular, until the pillars have the desired height.

In an embodiment, the doped ZnO layer is covered by a very thin metal layer, then heated up to create metal droplets with a size (diameter) around 100 nm (50-500 nm) on the surface of the ZnO layer.

FIG. 7 illustrates a SEM micrograph of a plurality of Au islands 23 arranged on the ZnO layer 12 in a hexagonal closed packed ordered array. The scale bar has the length of 200 nm.

These islands 23 act as an etch resist and are arranged in the arrangement corresponding to the desired arrangement of the ZnO pillars 13.

The ZnO may be etched away from regions uncovered by the Au islands to create a plurality of discrete ZnO pillars 13 having a height of 500-1500 nm and caped by the Au island as illustrated in FIG. 8. A Roth & Rau AK400 and the following etching parameters may be used: MW power—2000 W, RF power—100 W, Bias—200 V, H₂ flow—100 sccm, CH₄ flow—5 sccm, Ar flow—7 sccm, Pressure—0.2 mbar, Etching time—10 min and Achieved temperature—230° C.

Depending on the material used for the first transparent conductive layer, other methods of selectively removing the first transparent layer to produce a plurality of discrete pillars may be used, for example, photolithographic techniques or electron beam techniques.

In one embodiment, a superstrate is fabricated using a top down approach by Electron beam lithography (EBL) and subsequent Reactive Ion Etching (RIE) of ordinary TCO superstrate, for example glass/ZnO with dimension appropriate for a-Si cell.

FIG. 8 illustrates a micrograph of a tilted top view of a ZnO nanocolumn array created with the help of Reactive Ion Etching. The scale bar has the length of 200 nm.

FIG. 9 illustrates a micrograph of a tilted top view of ZnO nanocolumns covered by an intrinsic amorphous Si layer 23. Diameter of columns is over 300 nm. Scale bar has the length of 100 nm.

FIG. 10 illustrates a micrograph of a portion of a cross section of the whole nano-structure of a photovoltaic cell. Illustrated is a single ZnO nanocolumn with diameter 133 nm covered by a-Si (amorphous silicon) with a maximum diameter of 335 nm and a good conformal coating by the top thick ZnO layer deposited by LP CVD process. The scale bar has a length of 100 nm.

Deposition of the active silicon layer of the photovoltaic cell is based on conformal (or quasi-conformal) coverage over the nanocolumns (or nano/micro holes) by a CVD process, in particular plasma enhanced CVD process. Coverage of ZnO nanocolumns by an undoped amorphous silicon layer is illustrated in FIG. 9.

FIG. 10 illustrates a solar cell after the deposition of a second ZnO layer onto the silicon layer to form a thick conductive ZnO/white paint back reflector. Low pressure CVD was used to deposit this second ZnO layer. The micrograph illustrates that a good conformal coverage of nanocolumnar ZnO/a-Si (amorphous silicon) cell structure can be achieved using low pressure CVD.

An amorphous silicon solar cell, based on nanostructured TCO superstrate, with a new 3-dimensional “folded cell” design is schematically shown in FIG. 1. Thin (typically less than 200 nm) p-i-n amorphous silicon layer (or microcrystalline Si layer, or in the case of micromorph tandem an amorphous p-i-n layer followed by microcrystalline p-i-n) may be deposited over such 3-D front TCO contact.

FIG. 11 illustrates FTPS spectra of a folded amorphous silicon absorber layer having the structure illustrated in FIG. 10.

The amorphous silicon absorber quality is determined with the help of photocurrent spectroscopy. The nanostructured ZnO/amorphous silicon/ZnO structure (area 8×8 mm²) is used to measure subgap absorption spectra of the a-Si absorber layer with the help of Fourier Transform Photocurrent Spectroscopy (FTPS) to determine that a high quality absorber material can be deposited onto these nanostructured superstrates with columns of ZnO protruding from a sub-layer of ZnO.

Good absorber quality can be inferred from this picture. Urbach slope (measure of disorder in amorphous Si) is 45 meV.

This compares well with the optimized amorphous silicon material with E_{U}=44 meV. Also defect density, as characterized by the optical absorption coefficient at 1.2 eV, is low.

In FIG. 11, the “enhanced” FTPS absorption in the IR region is illustrated. Because of excellent light trapping in these nanostructured cells, the optical path is strongly increased here.

FIG. 12 illustrates optical absorption modeling of 3-D nanostructured a-Si solar cells having a nanocolumn structure of the first transparent layer, for optimized ZnO. This absorption in the absorber layer delivered the short-circuit current 19 mA/cm². The data is modeled without an antireflection coating.

By increasing the length of nanocolumns and their spacing this structure of the first transparent layer can also be used for micromorph cells.

Modelling the efficiency of such a nanostructured amorphous silicon cell (nanocolumn length around 600 nm) gives us the short-circuit current density in a range of 17.5-19.5 mA/cm². This translates, for V_{oc}=0.85-0.9 and FF=0.65-0.7, to 9.7-12.3% (stable) efficiency. The critical parameter of this design is the absorption loss in ZnO over which the a-Si (amorphous silicon) cell is folded. This also determines the I_{sc}. ZnO absorption has to be much lower compared to standard TCO, fortunately coupled with a lower electrical conductivity just appropriate to conduction over distances in micrometer range.

For a micromorph tandem cell design, a short-circuit current over 15 mA/cm² can be reached, which means that stable efficiencies over 15% should be achievable, even without intermediate reflector and with a microcrystalline layer thickness of around a half of micron. This translates into higher efficiency and lower production cost, as desired.

The modeling data indicates that a stable efficiency of more than 10% is achievable for amorphous Si cells and more than 15% stable efficiency is achievable for micromorph cells, with a very thin amorphous (less than 200 nm) and microcrystalline (around 500 nm) layers.

In further embodiments, a plurality of discrete indentations can be formed in the first transparent conductive layer using for example UV lithography or UV laser lithography. In these embodiments, the TCO layer, of an appropriate thickness for amorphous cell (or thicker for micromorph tandem) is etched to create the closely spaced holes (again, in a roughly six-fold coordinated arrangement), and the thin film Si layers are “folded into” these holes by depositing a silicon layer with plasma enhanced CVD. Finally, a LP CVD is used to conformally deposit ZnO top contact layer.

FIG. 13 illustrates a photovoltaic cell 10′ comprising a first transparent conductive layer 12′ having an alternative structure. In this embodiment, the first transparent conductive layer 12′ includes a plurality of discrete indentations or trenches 27 in its upper surface 28. In this embodiment, the indentations or trenches 27 are cylindrical and have a hexagonal close packed arrangement, as illustrated in the top view of FIG. 14. The indentations 27 can be fabricated by selective removal of the transparent conductive layer 12′ in the positions in which the indentations 27 are desired.

The indentations 27 may be fabricated by etching with the help of a patterned mask comprising a plurality of openings which is used during the etching process to define the array of indentations 27. This method is quicker than the use of electron beam lithography to produce the ZnO nanocolumns.

In contrast to the first embodiment, the mask extends across the surface of the first transparent conductive layer 12′ and includes a plurality of circular openings 30 exposing the zinc oxide of the first transparent layer 12′ underneath and therefore enabling the selective removal of the zinc oxide in these exposed regions. The selective removal process can be carried out for a time sufficient to create indentations 27 of the desired depth.

Alternatively a focused beam technique can be used to selectively remove portions of the transparent conductive layer 12′ without the use of an additional mask to produce a plurality of discrete holes 27 or trenches.

In the embodiment illustrated in FIG. 13, the first transparent conductive layer 12′ includes two sub-layers 31, 32. The doping level of the two sub-layers may be different so that the interface 33 between the two sub-layers 31, 32 acts as an etch stop. This can be achieved by adjusting the doping of the upper layer 32 so that it is etched more quickly than the material of the lower layer 31.

In an embodiment, the material of the two sub-layers 31, 32 is different and chosen so that the upper layer 32 is more quickly etched by a selected etchant than the material of the lower layer 31. In an embodiment, the lower layer 31 is SnO₂ and the upper layer 32 is ZnO doped with Aluminium or Boron and an etchant of dilute HCl is used to produce a plurality of discrete indentations in the upper ZnO layer 32.

The silicon layer 14′ is then conformally deposited by plasma enhanced chemical vapour deposition onto the first transparent conductive layer 12′ which has been structured to provide a plurality of indentations 27 according to one of the above embodiments. The side walls 34 and base 35 of the indentations 27 are covered with a layer of silicon.

The silicon layer 14 includes three sub-layers, which are not illustrated in the figure, the first being positively doped, the second being intrinsic and the third being negatively doped to provide a p-i-n active photovoltaic structure. Since the silicon layer 14′ is conformally deposited over the structured first transparent conductive layer 12′, it can be considered to have a folded structure as the junction comprises both vertical and horizontal regions.

FIG. 13 illustrates a similar folded structure of the charge separating junction as illustrated is in FIG. 1, with the help of this “Swiss cheese” design of the first transparent conductive layer 12′ with indentations 27.

In this embodiment, after deposition of the TCO layer 12′ by a CVD process, such as LPCVD, an etching process is performed which allows the TCO layer 12′ to be etched to a certain depth only to create the plurality of indentations 27. The silicon layer 14′ may be conformally deposited into the indentations 27 and onto the TCO layer 12′ using plasma enhanced CVD and the second transparent conductive layer 15′ deposited on the silicon layer 14′ by low-pressure CVD.

A photoresist can be used to mask a flat ZnO layer and optical lithography, for example standard UV lithography, may be used to create a plurality of openings in the photoresist layer to produce a mask. Reactive ion etching (RIE) may be used to fabricate the indentations in the first transparent conductive layer, which may comprise ZnO, for example, by etching away the ZnO in the regions exposed in the photoresist mask. Alternatively, imprint lithography could be used.

FIGS. 15 to 19 illustrate SEM micrographs of a ZnO transparent layer that has been etched using a patterned mask to produce a regular array of circular shaped indentations in the ZnO layer. These indentations are positioned in a hexagonal close-packed array. The protrusions are separated from one another by a honeycomb-type network of ZnO which protrudes from a ZnO sub-layer positioned on the substrate. The indentations each have a diameter of around 1.2 micrometres an a depth of 0.5 to 0.6 micrometres in this embodiment.

FIG. 20 illustrates a SEM micrograph and FIG. 21 illustrates an optical micrograph of a mask used to fabricate a first transparent conductive layer with a plurality of discrete indentations. The mask includes a plurality of circular openings arranged in a hexagonal close-packed array. The underlying ZnO can be etched away through the circular openings to produce a plurality of discrete indentations having the arrangement and approximate dimensions of the circular openings of the mask.

A tandem soar ell can be deposited onto the structured ZnO layer with the plurality of discrete indentations. A tandem solar cell is used herein to described a structure in which an amorphous p-i-n layer is first deposited onto the discrete indentations followed by the deposition of a microcrystalline p-i-n layer. The amorphous layer may have a total thickness of around 200 nm and the microcrystalline layer may have a total thickness of less than around one micrometer, for example around 500 nm. No intermediate reflector is used.

FIG. 22 illustrates a graph showing a comparison of the current/voltage characteristics of a tandem solar cell deposited onto a first transparent conductive layer including a plurality of discrete indentations and a flat transparent conductive layer. As can be seen from FIG. 22, the current measured for the tandem solar cell deposited onto the so called Swiss cheese ZnO with a plurality of discrete indentations in the first transparent conductive layer is greater than that for the tandem solar cell deposited on a flat ZnO layer without discrete indentations for voltages of less than around 1.2 V.

FIG. 23 illustrates a graph showing a comparison of the quantum efficiency of a tandem solar cell deposited onto a first transparent conductive layer including a plurality of discrete indentations and a flat transparent conductive layer. As can be seen from FIG. 23, the quantum efficiency (QE) measured for the tandem solar cell deposited onto the so called Swiss cheese ZnO with a plurality of discrete indentations in the first transparent conductive layer is greater than that for the tandem solar cell deposited on a flat ZnO layer without discrete indentations.

1. A method of fabricating a photovoltaic cell (10; 10′) comprising:
providing a substrate carrier (11; 11′),
depositing a first transparent conductive layer (12; 12′) onto the substrate carrier (11; 11′),
selectively removing portions of the first transparent conductive layer (12) and forming a plurality of discrete transparent conductive protruding regions (13), or selectively removing portions of the first transparent conductive layer (12′) and forming a plurality of discrete indentations (27) in the first transparent conductive layer (12′),
depositing a silicon layer (14; 14′) comprising a charge separating junction onto the plurality of discrete protruding regions (13) or onto the plurality of discrete indentations (27) by chemical vapour deposition, and
depositing a second transparent conductive layer (15; 15′) on the silicon layer (14; 14′) by chemical vapour deposition.

2. The method according to claim 1, wherein
the silicon layer (14; 14′) is deposited by plasma enhanced chemical vapour deposition.

3. The method according to claim 1 or claim 2, wherein the first transparent conductive layer (12; 12′) and/or the second transparent conductive layer (15; 15′) is deposited by low pressure chemical vapour deposition.

4. The method according to one of claims 1 to 3, wherein the silicon layer (14; 14′) is deposited conformally onto the plurality of discrete transparent conductive protruding regions (13) or onto the plurality of discrete indentations (27).

5. The method according to one of claims 1 to 4, wherein the second transparent conductive layer (15; 15′) is deposited conformally onto the silicon layer (14; 14′).

6. The method according to one of claims 1 to 5, wherein the portions of the first transparent conducive layer (12) are selectively removed to form a closed sub-layer (17) from which the plurality of discrete transparent conductive protruding regions (13) extend, the plurality of discrete transparent conductive protruding regions (13) comprising material of the first transparent conductive layer (12).

7. The method according to claim 6, wherein
the silicon layer (14) is deposited conformally onto the sub-layer (17) and onto the plurality of the discrete transparent conductive protruding regions (13).

8. The method according to one of claims 1 to 6, wherein the portions of the first transparent layer (12) are removed to produce the plurality of discrete transparent conductive protruding portions (13) with a diameter in the range of 150 nm to 200 nm and a height of 500 nm to 700 nm, or the portions of the first transparent layer (12′) are removed to produce the plurality of discrete indentations (27) with a diameter in the range of 150 nm to 200 nm and a height of 500 nm to 700 nm.

9. The method according to claim 8, wherein
after deposition of the silicon layer (14; 14′), an outer surface of the silicon layer (14; 14′) comprises a plurality of protruding regions having a diameter of at least 300 nm.

10. The method according to one of claims 1 to 9, wherein the second transparent conductive layer (15; 15′) fills regions between adjacent protruding regions comprising silicon or fills indentations lined with silicon.

11. The method according to one of claims 1 to 10, wherein the first transparent conductive layer (12; 12′) is structured by reactive ion etching or electron beam lithography to produce the plurality of discrete transparent conductive protruding regions (13) or the plurality of discrete indentations (27).

12. The method according to one of claims 1 to 11, wherein a plurality of discrete metal islands (23) are deposited on the first transparent conductive layer (12) and regions of the first transparent conductive layer (12) outside of the metal islands are removed by selective etching to produce a plurality of discrete protruding regions (13) comprising material of the first transparent conductive layer (12).

13. Method according to one of claims 1 to 11, wherein
a patterned resist layer is deposited on the first transparent conductive layer (12) and the first transparent conductive layer (12) is selectively etched to produce the plurality of discrete indentations (27) in the first transparent conductive layer (12).

14. A photovoltaic cell (10; 10′) comprising:
a substrate carrier (11; 11′);
a first transparent conductive layer (12; 12′) positioned on the substrate carrier (11; 11′) comprising
a plurality of discrete transparent conductive protruding regions (13), the plurality of discrete transparent conductive protruding regions (13) having a diameter in the range of 150 nm to 200 nm and a height of 500 nm to 700 nm, or
a plurality of discrete indentations (27) having a diameter in the range of 150 nm to 200 nm and a height of 500 nm to 700 nm,
a silicon layer (14; 14′) comprising a charge separating junction covering the plurality of discrete transparent conductive protruding regions (13) or the plurality of discrete indentations (27), and
a second transparent conductive layer (15; 15′) positioned on the silicon layer (14; 14′).

15. The photovoltaic cell according to claim 14, wherein the silicon layer (14; 14′) is positioned conformally on the plurality of discrete transparent conductive protruding regions (13) or on the plurality of discrete indentations (27).

16. The photovoltaic cell according to claim 14 or claim 15, wherein the silicon layer (14; 14′) comprises a plurality of protrusions having a diameter of 300 nm or greater.

17. The photovoltaic cell according to one of claims 14 to 16, wherein
the second transparent conductive layer (15; 15′) is positioned conformally on the silicon layer (14; 14′).

18. The photovoltaic cell according to one of claims 14 to 17, wherein the plurality of discrete transparent conductive protruding regions (13) or plurality of discrete indentations (27) extend generally perpendicular to a major plane (18) of the substrate carrier (11; 11′).

19. The photovoltaic cell according to one of claims 14 to 18, wherein the second transparent conductive layer (15; 15′) fills regions between protruding regions of the silicon layer (14; 14′).
